(19) United States
(12) Patent Application Publication
(10) Pub. No.: US 2026/0291167 A1
(43) Pub. Date: Sep. 24, 2026

(54) LASER IRRADIATION APPARATUS AND LASER PROCESSING APPARATUS

(71) Applicant: SEIKO EPSON CORPORATION, Tokyo (JP)

(72) Inventors: Yoshitomo KUMAI, OKAYA-SHI (JP); Yoji KITANO, CHINO-SHI (JP)

(73) Assignee: SEIKO EPSON CORPORATION, Tokyo (JP)

(21) Appl. No.: 19/570,191

(22) Filed: Mar. 18, 2026

(30) Foreign Application Priority Data
Mar. 19, 2025 (JP) 2025-044588

(51) Int. Cl. H01S 5/024; B23K 26/70; H01S 5/11; H01S 5/42

(52) U.S. Cl. CPC H01S 5/02423; B23K 26/703; H01S 5/11; H01S 5/42

(57) ABSTRACT

A laser irradiation apparatus includes: a laser array having laser elements including a first laser element and a second laser element; and a cooling substrate, wherein the cooling substrate includes: a substrate including a mounting surface on which the laser array is mounted; a supply flow path extending in a direction crossing the mounting surface and supplying a coolant to an inside of the substrate; a first flow path extending along the mounting surface and cooling the first laser element of the laser array via the substrate; and a second flow path extending along the mounting surface and cooling the second laser element of the laser array via the substrate, in a plan view, the first flow path and the second flow path are branched from the supply flow path between the first laser element and the second laser element to thereby cause the coolant to flow, respectively.

The present application is based on, and claims priority from JP Application Serial Number 2025-044588, filed Mar. 19, 2025, the disclosure of which is hereby incorporated by reference herein in its entirety.

### BACKGROUND

### 1. Technical Field

The present disclosure relates to a laser irradiation apparatus and a laser processing apparatus.

### 2. Related Art

JP-A-2015-153963 discloses a semiconductor laser device in which a passage through which a coolant flows is provided inside a heatsink on which a semiconductor laser array element having a plurality of laser elements is mounted.

JP-A-2015-153963 is an example of the related art.

In the semiconductor laser device described above, since the coolant is not caused to flow inside the heatsink in consideration of the cooling characteristics of the plurality of laser elements, there is a concern that the temperature may vary among the plurality of laser elements.

### SUMMARY

In order to solve the problem described above, according to an aspect of the present disclosure, there is provided a laser irradiation apparatus including: a plurality of laser elements including a first laser element and a second laser element; and a cooling substrate configured to cool the plurality of laser elements, wherein the cooling substrate includes: a substrate including a mounting surface on which the plurality of laser elements is mounted; a supply flow path extending in a direction crossing the mounting surface and configured to supply a coolant to an inside of the substrate; a first flow path extending along the mounting surface and configured to cool the first laser element via the substrate; and a second flow path extending along the mounting surface and configured to cool the second laser element via the substrate, in a plan view of the mounting surface, the first flow path and the second flow path are branched from the supply flow path between the first laser element and the second laser element to thereby cause the coolant to flow, respectively.

According to another aspect of the present disclosure, there is provided a laser processing apparatus including: a laser irradiation head using the laser irradiation apparatus according to the aspect described above; and a stage on which a workpiece to be irradiated with the laser light by the laser irradiation head is placed.

### BRIEF DESCRIPTION OF THE DRAWINGS

FIG. 1 is a perspective view showing a schematic configuration of a laser processing apparatus according to an embodiment.

FIG. 2 is a perspective view showing a configuration of a laser irradiation apparatus.

FIG. 3 is a diagram showing a configuration of a main part of the laser irradiation apparatus.

FIG. 4 is a diagram showing a configuration of a main part of a laser irradiation apparatus according to a first modified example.

FIG. 5 is a diagram showing a configuration of a main part of a laser irradiation apparatus according to a second modified example.

FIG. 6 is a diagram showing a configuration of a main part of a laser irradiation apparatus according to a third modified example.

FIG. 7 is a diagram showing a configuration of a main part of a laser irradiation apparatus according to a fourth modified example.

### DESCRIPTION OF EMBODIMENTS

An embodiment of the present disclosure will hereinafter be described with reference to the drawings.

In the following drawings, elements are drawn at different dimensional scales in some cases in order to make the elements eye-friendly.

### Embodiment

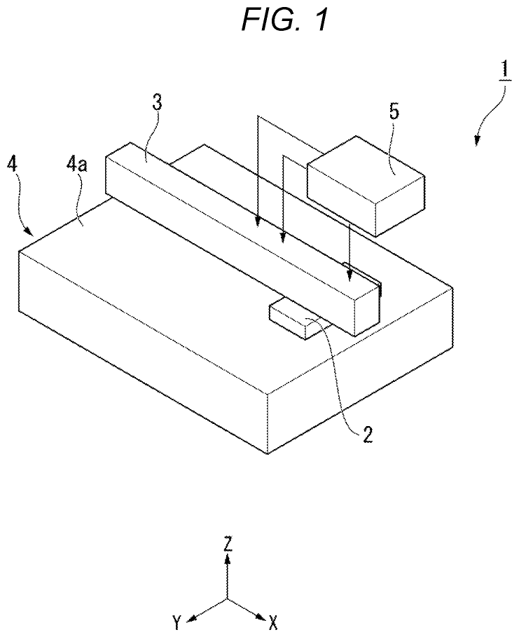

FIG. 1 is a perspective view showing a schematic configuration of a laser processing apparatus according to the present embodiment.

As illustrated in FIG. 1, the laser processing apparatus 1 of the present embodiment includes a laser irradiation apparatus 2, a moving mechanism 3, a stage 4, and a controller 5. The laser processing apparatus 1 is, for example, a metal 3D printer using selective laser melting (SLM).

In the following description, an X-Y-Z orthogonal coordinate system is used as necessary.

In each drawing, the X axis is an axis along a moving direction of the laser irradiation apparatus 2 with respect to the stage 4. The Y axis is an axis orthogonal to the X axis, and the X-Y plane is a plane parallel to a placement surface 4a of the stage 4. The Z axis is an axis orthogonal to the X axis and the Y axis, and is an axis along a vertical direction.

Further, in the description of the present embodiment, a direction along the Z axis is referred to as an “up-down direction Z”, +Z is referred to as an “upper side”, −Z is referred to as a “lower side”, a direction along the X axis is referred to as a “left-right direction X”, +X is referred to as a “right side”, −X is referred to as a “left side”, a direction along the Y axis is referred to as a “front-rear direction Y”, +Y is referred to as a “front side”, and −Y is referred to as a “rear side”.

Note that the up-down direction Z, the left-right direction X, and the front-rear direction Y are merely names for describing the arrangement relationship of the components of the laser processing apparatus 1, but do not define the actual installation posture and direction in the laser processing apparatus 1.

The laser irradiation apparatus 2 is a laser irradiation head that irradiates a workpiece W placed on the stage 4 with laser light L.

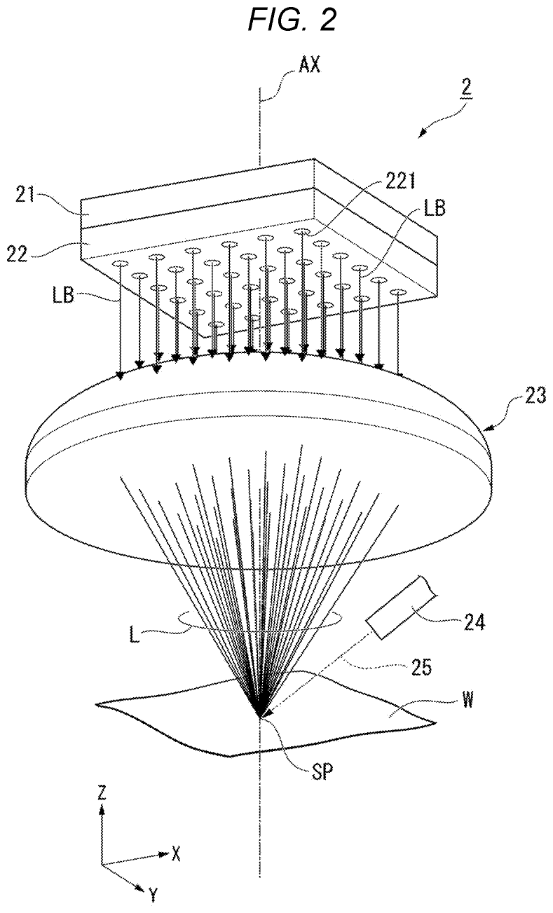

FIG. 2 is a perspective view showing a configuration of the laser irradiation apparatus 2. As illustrated in FIG. 2, the laser irradiation apparatus 2 includes a cooling substrate 21, a laser array 22 mounted on the cooling substrate 21, a condenser lens 23, and a material supply unit 24.

The cooling substrate 21 cools the laser array 22. The laser array 22 includes a plurality of laser elements 221. The plurality of laser elements 221 is arranged in a matrix on the cooling substrate 21. Each of the laser elements 221 emits a laser beam LB. In the example in FIG. 2, the planar shape of the laser element 221 is a circle.

The laser element 221 is, for example, a photonic crystal surface emitting laser (PCSEL) element using a photonic crystal effect. The laser beam LB emitted from the laser element 221 formed of the PCSEL element is narrow in radiation angle and high in light output.

The emission directions of the laser beams LB from the plurality of laser elements 221 are parallel to each other. The emission direction of the laser beam LB from the laser element 221 is a direction along the Z axis that is orthogonal to a virtual plane on which the plurality of laser elements 221 is arranged and coincides with the optical axis AX of the laser irradiation apparatus 2.

The condenser lens 23 is a convex lens, and converges the laser beams LB from the plurality of laser elements 221 toward the convergence point SP to thereby generate the high-power laser light L. The surface of the workpiece W is disposed at the convergence point SP of the laser light L. In this way, the laser irradiation apparatus 2 irradiates the surface of the workpiece W with the laser light L obtained by converging the plurality of laser beams LB.

The material supply unit 24 is configured with, for example, a pipe member through which the material powder can flow, and ejects a material powder 25 toward the workpiece W. As the material powder, metal powder of, for example, stainless steel, a nickel-based alloy, a cobalt-based alloy, or titanium is used. It is sufficient for the material supplied from the material supply unit 24 to the workpiece W to be metal, and the material may be, for example, a metal wire having a linear shape.

Based on such a configuration, the laser irradiation apparatus 2 can perform additive manufacturing for melting metal and forming a metal layer on the surface of the workpiece W by irradiating the surface of the workpiece W with the laser light L obtained by converging the plurality of laser beams LB and supplying the metal powder to the workpiece W.

As illustrated in FIG. 1, the moving mechanism 3 is capable of moving the laser irradiation apparatus 2 in one direction. The moving mechanism 3 changes the relative position between the laser irradiation apparatus 2 and the stage 4. In the case of the present embodiment, driving of the moving mechanism 3 is controlled by the controller 5.

For example, the moving mechanism 3 moves the laser irradiation apparatus 2 to cause the laser irradiation apparatus 2 and the workpiece W to face each other. The laser processing apparatus 1 performs the processing described above by irradiating the workpiece W on the stage 4 with the laser light L from the laser irradiation apparatus 2 in a state where the laser irradiation apparatus 2 and the workpiece W face each other.

The stage 4 has the placement surface 4a on which the workpiece W is placed.

The stage 4 is a biaxial stage that moves the placement surface 4a on which the workpiece W is placed in biaxial directions of the left-right direction X and the front-rear direction Y. The stage 4 may adjust the position of the workpiece W with respect to the laser irradiation apparatus 2 by moving the placement surface 4a. Accordingly, the workpiece W can be accurately irradiated with the laser light L.

In the case of the present embodiment, driving of the stage 4 is controlled by the controller 5.

The controller 5 is configured with, for example, a computer including a processor, a main storage device, and an input/output interface for receiving input of a signal from and outputting a signal to the outside. The controller 5 exerts various functions by the processor executing programs read into the main storage device. Thus, the controller 5 controls driving of the laser irradiation apparatus 2, the moving mechanism 3, and the stage 4. The controller 5 may be implemented by a combination of a plurality of circuits instead of a computer.

Here, since the laser irradiation apparatus 2 of the present embodiment uses the PCSEL element as the laser element 221, the heat generation amount of each laser element 221 is large. Therefore, each laser element 221 cannot be efficiently cooled, and the output of the laser light L may vary due to temperature variation between the laser elements 221 in some cases. When the output of the laser light L varies as described above, there is a possibility that the irradiation amount of the laser light L becomes unstable, and the processing accuracy of the workpiece W may be reduced.

In contrast, in the laser irradiation apparatus 2 of the present embodiment, the laser array 22 is cooled by the cooling substrate 21 to thereby suppress the temperature variation among the laser elements 221. Accordingly, it is possible to improve the processing accuracy of the workpiece W by stabilizing the irradiation amount of the workpiece W with the laser light L.

A configuration of the laser irradiation apparatus 2 of the present embodiment will hereinafter be described in detail.

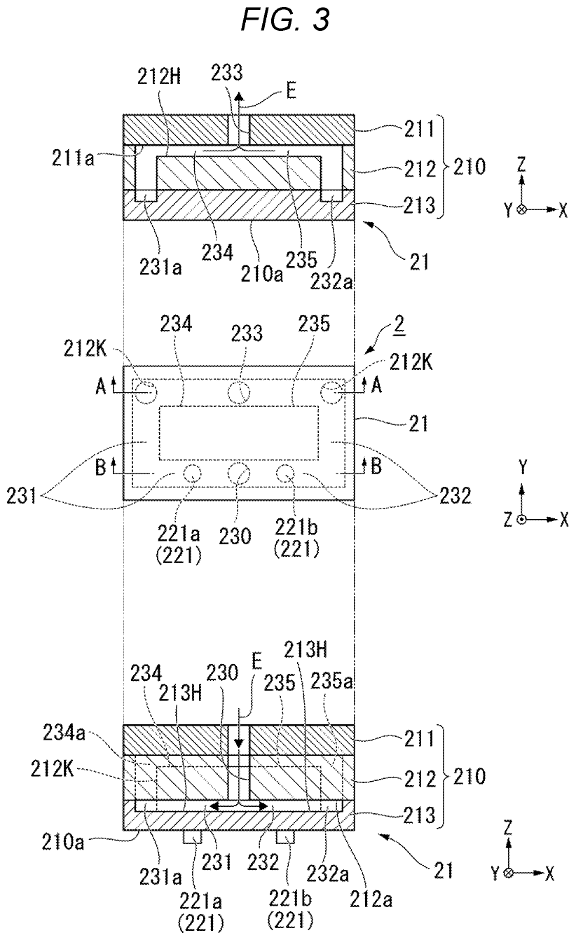

FIG. 3 is a diagram illustrating a configuration of a main part of the laser irradiation apparatus 2. The middle part of FIG. 3 is a plan view illustrating a configuration of a main part of the laser irradiation apparatus 2 viewed from the +Z side toward the −Z side, the upper part of FIG. 3 is a cross-sectional view taken along the arrowed line A-A in the middle part, and the lower part of FIG. 3 is a cross-sectional view taken along the arrowed line B-B in the middle part. FIG. 3 is a diagram illustrating a peripheral configuration of a first laser element 221a and a second laser element 221b as any two laser elements adjacent to each other out of the plurality of laser elements 221 in the laser irradiation apparatus 2.

As illustrated in FIG. 3, the cooling substrate 21 includes a substrate 210, a supply flow path 230, a first flow path 231, a second flow path 232, a discharge flow path 233, a first connection flow path 234, and a second connection flow path 235.

The substrate 210 includes a mounting surface 210a on which the laser array 22 is mounted. The substrate 210 of the present embodiment has a laminated structure, and includes, for example, a first layer 211, a second layer 212, and a third layer 213. The first layer 211, the second layer 212, and the third layer 213 are stacked in order from the upper side toward the lower side in the up-down direction Z. Therefore, the surface of the third layer 213 corresponds to the mounting surface 210a.

The first layer 211, the second layer 212, and the third layer 213 are made of a metal material excellent in thermal conductivity such as copper. The first layer 211, the second layer 212, and the third layer 213 are bonded via an adhesive (not illustrated) or the like. The number of layers constituting the substrate 210 is not limited to three.

The supply flow path 230 is a flow path that extends in the up-down direction Z crossing the mounting surface 210a and supplies the coolant E to the inside of the substrate 210 from the outside. The supply flow path 230 is formed so as to penetrate the first layer 211 and the second layer 212 in the up-down direction Z.

The first flow path 231 is a flow path through which the coolant E supplied by the supply flow path 230 flows. The first flow path 231 extends along the mounting surface 210a and cools the first laser element 221a via the third layer 213. That is, the first flow path 231 is provided to an upper layer of the first laser element 221a out of the third layer 213. Therefore, the heat of the first laser element 221a is transferred to the coolant E in the first flow path 231 disposed above the third layer 213, and the coolant E warmed by the heat from the first laser element 221a flows downstream of the first flow path 231. Therefore, the heat can be efficiently dissipated from the first laser element 221a.

The first flow path 231 is formed by cutting out a part of a boundary surface between the third layer 213 and the second layer 212. That is, the first flow path 231 is formed of a space defined by a surface 212a of the second layer 212 and a recess 213H formed in the third layer 213.

The second flow path 232 is a flow path through which the coolant E supplied by the supply flow path 230 flows. The second flow path 232 extends along the mounting surface 210a and cools the second laser element 221b via the third layer 213. That is, the second flow path 232 is formed in a layer which is an upper layer of the second laser element 221b in the third layer 213, and is the same layer as the first flow path 231 in the substrate 210. Therefore, the heat of the second laser element 221b is transferred to the coolant E in the second flow path 232 disposed in an upper layer of the third layer 213, and the coolant E warmed by the heat from the second laser element 221b flows downstream of the second flow path 232. Therefore, the heat can be efficiently dissipated from the second laser element 221b.

The second flow path 232 is formed by cutting out a part of a boundary surface between the third layer 213 and the second layer 212. That is, the second flow path 232 is formed of a space defined by the surface 212a of the second layer 212 and the recess 213H formed in the third layer 213.

Hereinafter, a state in which the mounting surface 210a is viewed from the normal direction of the mounting surface 210a in a plan view is simply referred to as a “plan view”.

In plan view, each of the first flow path 231 and the second flow path 232 is branched from the supply flow path 230 between the first laser element 221a and the second laser element 221b. Therefore, the coolant E flows to the first flow path 231 and the second flow path 232 via the supply flow path 230. In the case of the present embodiment, the flow rates of the coolant E branched from the supply flow path 230 and supplied to the first flow path 231 and the second flow path 232 are the same. Accordingly, the difference in temperature between the coolant E flowing through the first flow path 231 and the coolant E flowing through the second flow path 232 can be reduced.

In the state of plan view, the supply flow path 230 is located at the center of the front side (+Y side) of the substrate 210. In the state of plan view, the first flow path 231 extends from the supply flow path 230 to the left end of the substrate 210, is then bent, and extends toward the rear side (−Y side). In the state of plan view, the second flow path 232 extends to the right end of the substrate 210, is then bent, and extends toward the rear side (−Y side).

The lateral width of the first flow path 231 is preferably equal to or greater than the outer diameter of the first laser element 221a. The lateral width of the second flow path 232 is preferably equal to or greater than the outer diameter of the second laser element 221b. According to this configuration, since the first flow path 231 and the second flow path 232 entirely overlap the first laser element 221a and the second laser element 221b, the first laser element 221a and the second laser element 221b can be efficiently cooled.

The discharge flow path 233 is a flow path that extends in the up-down direction Z crossing the mounting surface 210a and discharges, from the substrate 210, the coolant E having cooled the first laser element 221a and the second laser element 221b. In plan view, the discharge flow path 233 is disposed at a position different from the positions of the supply flow path 230, the first flow path 231, and the second flow path 232. In plan view, the discharge flow path 233 is located at the rear side (−Y side) of the supply flow path 230. Therefore, since the discharge flow path 233 does not affect the layout of the supply flow path 230, the first flow path 231, and the second flow path 232, it is possible to increase the degree of freedom in designing the supply flow path 230, the first flow path 231, and the second flow path 232.

The first connection flow path 234 is a flow path that extends along the mounting surface 210a to couple the first flow path 231 and the discharge flow path 233. One end side of the first connection flow path 234 is coupled to the first flow path 231, and the other end side of the first connection flow path 234 is coupled to the discharge flow path 233.

In the case of the present embodiment, the first connection flow path 234 is provided to a layer different from the layer of the first flow path 231 in the substrate 210. Specifically, the first connection flow path 234 is configured by cutting out a part of a boundary surface between the second layer 212 and the first layer 211. That is, the first connection flow path 234 is formed of a space defined by a surface 211a of the first layer 211 and a recess 212H formed in the second layer 212. Therefore, one end 234a of the first connection flow path 234 is coupled to a terminal end 231a of the first flow path 231 via a through hole 212K penetrating the second layer 212 in the up-down direction Z.

The second connection flow path 235 is a flow path that extends along the mounting surface 210a to couple the second flow path 232 and the discharge flow path 233. One end side of the second connection flow path 235 is coupled to the second flow path 232, and the other end side of the second connection flow path 235 is coupled to the discharge flow path 233.

The second connection flow path 235 is provided to a layer different from the layer of the second flow path 232 in the substrate 210. Specifically, the second connection flow path 235 is configured by cutting out a part of a boundary surface between the second layer 212 and the first layer 211. That is, the second connection flow path 235 is formed of a space defined by the surface 211a of the first layer 211 and the recess 212H formed in the second layer 212. Therefore, one end 235a of the second connection flow path 235 is coupled to a terminal end 232a of the second flow path 232 via a through hole 212K penetrating the second layer 212 in the up-down direction Z.

In the state of plan view, the first connection flow path 234 extends from the front side (+Y side) toward the rear side (−Y side) at the left end of the substrate 210, is then bent toward the right side (+X side), and extends toward the center. The second connection flow path 235 extends from the front side (+Y side) toward the rear side (−Y side) at the right end of the substrate 210, is then bent toward the left side (−X side), and extends toward the center. Then, the first connection flow path 234 and the second connection flow path 235 join and are coupled to the discharge flow path 233.

The first connection flow path 234 and the second connection flow path 235 may be provided to the same layer as the layer of the first flow path 231 and the second flow path 232 in the substrate 210. In this case, the discharge flow path 233 is formed to penetrate the second layer 212 and the first layer 211 in the up-down direction Z.

As described above, the laser irradiation apparatus 2 of the present embodiment includes the laser array 22 including the plurality of laser elements 221 including the first laser element 221a and the second laser element 221b, and the cooling substrate 21 that cools the laser array 22. The cooling substrate 21 includes the substrate 210 including the mounting surface 210a on which the laser array 22 is mounted, the supply flow path 230 that extends in a direction crossing the mounting surface 210a and supplies the coolant E into the substrate 210, the first flow path 231 that extends along the mounting surface 210a and cools the first laser element 221a via the substrate 210, and the second flow path 232 that extends along the mounting surface 210a and cools the second laser element 221b via the substrate 210. In plan view of the mounting surface 210a, each of the first flow path 231 and the second flow path 232 is branched from the supply flow path 230 between the first laser element 221a and the second laser element 221b. The coolant E flows to the first flow path 231 and the second flow path 232 via the supply flow path 230.

According to the laser irradiation apparatus 2 of the present embodiment, by reducing the difference between the cooling performance of the first laser element 221a with the first flow path 231 and the cooling performance of the second laser element 221b with the second flow path 232, the temperature variation between the first laser element 221a and the second laser element 221b can be reduced.

In the present embodiment, the first laser element 221a and the second laser element 221b are any two laser elements adjacent to each other out of the plurality of laser elements 221. Therefore, according to the laser irradiation apparatus 2 of the present embodiment, the temperature variation between two laser elements adjacent to each other out of the plurality of laser elements 221 can be reduced.

Therefore, according to the laser irradiation apparatus 2 of the present embodiment, it is possible to stabilize the irradiation amount of the laser light L by suppressing the temperature variation between the first laser element 221a and the second laser element 221b adjacent to each other out of the plurality of laser elements 221.

The laser processing apparatus 1 of the present embodiment includes the laser irradiation apparatus 2 described above and the stage 4 on which the workpiece W irradiated with the laser light L by the laser irradiation apparatus 2 is placed.

According to the laser processing apparatus 1 of the present embodiment, by stabilizing the irradiation amount of the laser light L to the workpiece W, the workpiece W can be accurately processed by the processing with the laser light L.

In the laser irradiation apparatus 2 of the embodiment described above, the plurality of laser elements 221 is arranged in a matrix on the cooling substrate 21, but the plurality of laser elements 221 may be concentrically arranged on the cooling substrate 21.

The technical scope of the present disclosure is not limited to the embodiment described above, and various changes can be made thereto to the extent that the changes do not depart from the intent of the present disclosure.

### First Modified Example

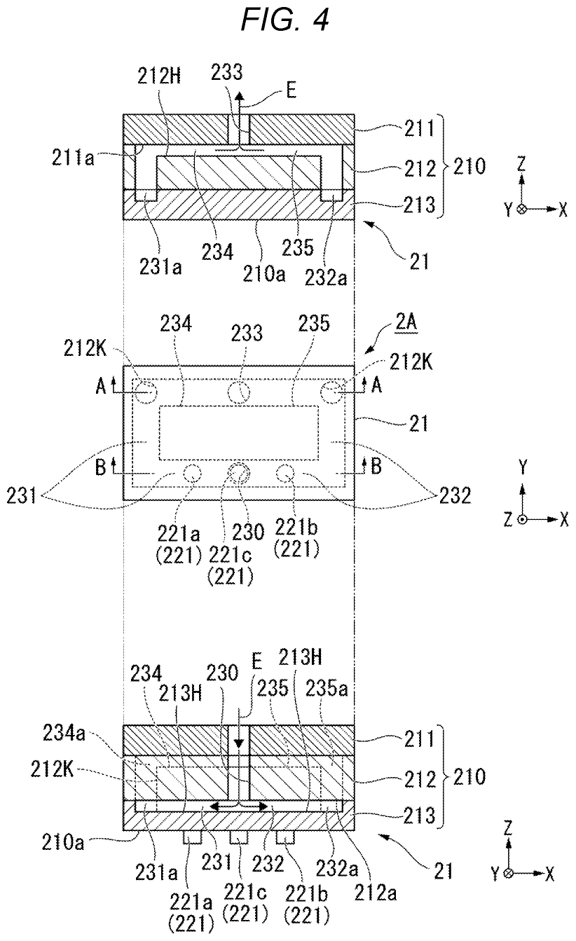

FIG. 4 is a diagram showing a configuration of a main part of a laser irradiation apparatus according to a first modified example. The middle part of FIG. 4 is a plan view illustrating a configuration of a main part of the laser irradiation apparatus viewed from the +Z side toward the −Z side, the upper part of FIG. 4 is a cross-sectional view taken along the arrowed line A-A in the middle part, and the lower part of FIG. 4 is a cross-sectional view taken along the arrowed line B-B in the middle part. FIG. 4 is a diagram illustrating a peripheral configuration of a first laser element 221a, a second laser element 221b, and a third laser element 221c as any three laser elements adjacent to each other out of the plurality of laser elements in a laser irradiation apparatus 2A. In the present modified example, the same reference numerals are given to the same components and members as those of the embodiment described above to omit the detailed description thereof.

As shown in FIG. 4, in plan view of the mounting surface 210a, the third laser element 221c is disposed between the first laser element 221a and the second laser element 221b. Specifically, the third laser element 221c is disposed at a position where the third laser element 221c overlaps the supply flow path 230.

According to the laser irradiation apparatus 2A of the present modified example, the third laser element 221c disposed directly below the supply flow path 230 can be cooled by the coolant E flowing through the supply flow path 230. The coolant E that has cooled the third laser element 221c is separated into two and supplied to the first flow path 231 and the second flow path 232. The flow rate of the coolant E that cools the third laser element 221c is about twice the flow rate of the coolant E that cools each of the laser elements 221a and 221b in the first flow path 231 and the second flow path 232. Therefore, the temperature of the coolant E after cooling the third laser element 221c is less likely to change. Therefore, by reducing the difference among the cooling performance of the third laser element 221c with the supply flow path 230, the cooling performance of the first laser element 221a with the first flow path 231, and the cooling performance of the second laser element 221b with the second flow path 232, the temperature variation among the first laser element 221a, the second laser element 221b, and the third laser element 221c can be reduced.

In the present modified example, the first laser element 221a, the third laser element 221c, and the second laser element 221b are any three adjacent laser elements out of the plurality of laser elements 221. Therefore, according to the laser irradiation apparatus 2A of the present modified example, it is possible to reduce the temperature variation among three adjacent laser elements out of the plurality of laser elements 221.

Therefore, according to the laser irradiation apparatus 2A of the present modified example, it is possible to stabilize the irradiation amount of the laser light L by suppressing the temperature variation among the first laser element 221a, the third laser element 221c, and the second laser element 221b adjacent to each other out of the plurality of laser elements 221.

### Second Modified Example

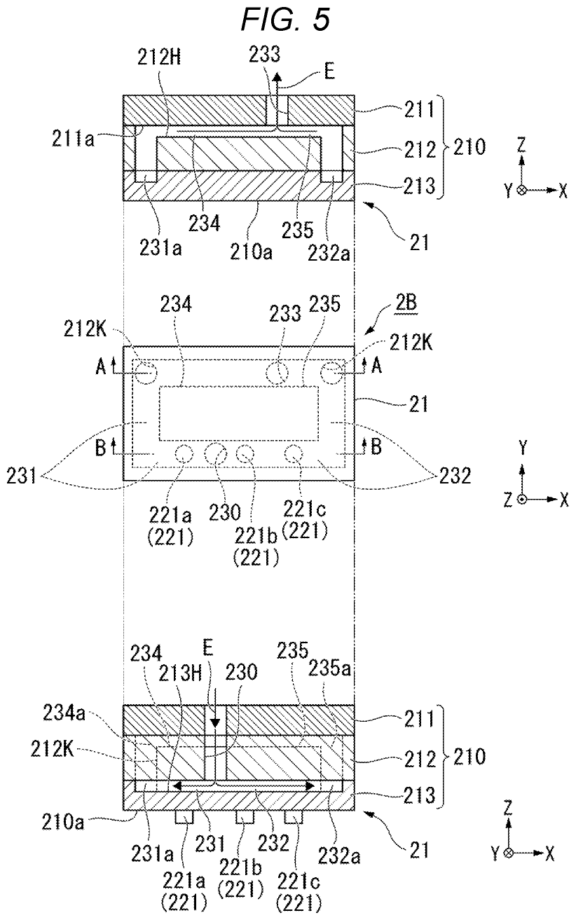

FIG. 5 is a diagram showing a configuration of a main part of a laser irradiation apparatus according to a second modified example. The middle part of FIG. 5 is a plan view illustrating a configuration of a main part of the laser irradiation apparatus viewed from the +Z side toward the −Z side, the upper part of FIG. 5 is a cross-sectional view taken along the arrowed line A-A in the middle part, and the lower part of FIG. 5 is a cross-sectional view taken along the arrowed line B-B in the middle part. FIG. 5 is a diagram illustrating a peripheral configuration of a first laser element 221a, a second laser element 221b, and a third laser element 221c as any three laser elements adjacent to each other out of the plurality of laser elements in a laser irradiation apparatus 2B. In the present modified example, the same reference numerals are given to the same components and members as those of the embodiment described above to omit the detailed description thereof.

As illustrated in FIG. 5, in the plan view of the mounting surface 210a, the third laser element 221c is disposed at the right side (+X side) of the second laser element 221b. That is, the third laser element 221c is disposed downstream of the second laser element 221b in the second flow path 232.

In the case of the present modified example, the discharge flow path 233 is disposed at a position corresponding to a portion between the second laser element 221b and the third laser element 221c in the front-rear direction Y in plan view. The discharge flow path 233 may be disposed at the rear side (−Y side) of the supply flow path 230 in plan view.

Here, as a comparative example, there is considered when the first laser element 221a, the second laser element 221b, and the third laser element 221c are arranged in order in the direction in which the coolant E flows. In this case, the temperature variation between the first laser element 221a located most upstream in the flow of the coolant E and the third laser element 221c located most downstream in the flow of the coolant E increases.

In contrast, according to the laser irradiation apparatus 2B of the present modified example, similarly to the embodiment described above, by reducing the difference between the cooling performance of the first laser element 221a with the first flow path 231 and the cooling performance of the second laser element 221b with the second flow path 232, the temperature variation between the first laser element 221a and the second laser element 221b can be reduced.

In the case of the present modified example, the temperature of the third laser element 221c located downstream of the second laser element 221b in the second flow path 232 is higher than the temperatures of the first laser element 221a and the second laser element 221b. However, the temperature variation caused among the laser elements in the configuration of the present modified example is smaller than the temperature variation caused in the configuration of the comparative example.

Therefore, according to the laser irradiation apparatus 2B of the present modified example, it is possible to stabilize the irradiation amount of the laser light L by suppressing the temperature variation among the first laser element 221a, the second laser element 221b, and the third laser element 221c adjacent to each other out of the plurality of laser elements 221.

In the present modified example, when the third laser element 221c is disposed downstream of the second laser element 221b in the second flow path 232 has been described as an example, but the third laser element 221c may be disposed downstream of the first laser element 221a in the first flow path 231.

### Third Modified Example

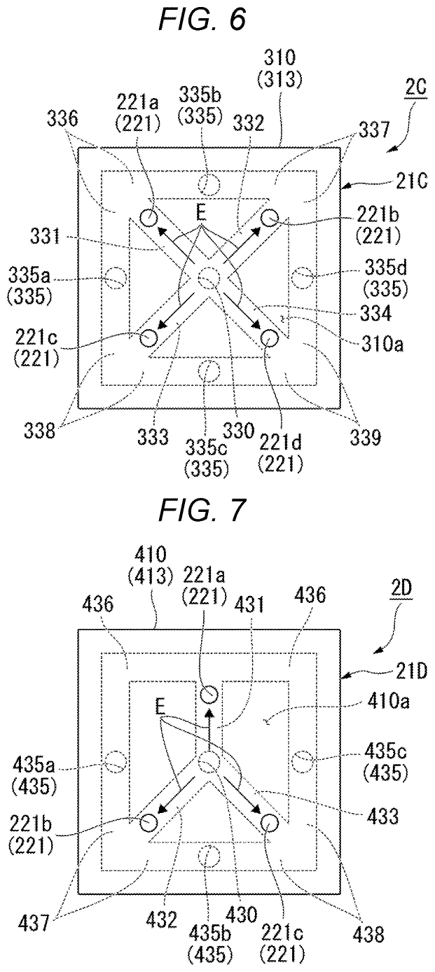

FIG. 6 is a diagram showing a configuration of a main part of a laser irradiation apparatus according to a third modified example. FIG. 6 is a plan view illustrating a configuration of a main part of a laser irradiation apparatus 2C viewed from the −Z side toward the +Z side. FIG. 6 is a diagram illustrating a peripheral configuration of a first laser element 221a, a second laser element 221b, a third laser element 221c, and a fourth laser element 221d as any four laser elements adjacent to each other out of the plurality of laser elements 221 in the laser irradiation apparatus 2C.

As illustrated in FIG. 6, a cooling substrate 21C of the present modified example includes a substrate 310, a supply flow path 330, a first flow path 331, a second flow path 332, a third flow path 333, a fourth flow path 334, a discharge flow path 335, a first connection flow path 336, a second connection flow path 337, a third connection flow path 338, and a fourth connection flow path 339.

The first flow path 331 extends along a mounting surface 310a of the substrate 310, and cools the first laser element 221a via a third layer 313 of the substrate 310.

The second flow path 332 extends along the mounting surface 310a of the substrate 310, and cools the second laser element 221b via the third layer 313 of the substrate 310.

The third flow path 333 extends along the mounting surface 310a of the substrate 310, and cools the third laser element 221c via the third layer 313 of the substrate 310.

The fourth flow path 334 extends along the mounting surface 310a of the substrate 310, and cools the fourth laser element 221d via the third layer 313 of the substrate 310.

In the plan view of the mounting surface 310a, the first flow path 331, the second flow path 332, the third flow path 333, and the fourth flow path 334 are branched from the supply flow path 330 in four directions different from each other. The first flow path 331 and the fourth flow path 334 extend in respective directions opposite to each other, and the second flow path 332 and the third flow path 333 extend in respective directions opposite to each other. The direction in which the first flow path 331 and the fourth flow path 334 extend and the direction in which the second flow path 332 and the third flow path 333 extend are orthogonal to each other.

In the plan view of the mounting surface 310a, the first laser element 221a, the second laser element 221b, the third laser element 221c, and the fourth laser element 221d are arranged in a square lattice shape. The supply flow path 330 is located at the center of the square lattice.

The discharge flow path 335 in the present modified example includes a first discharge path 335a, a second discharge path 335b, a third discharge path 335c, and a fourth discharge path 335d. Each of the discharge paths 335a to 335d is a flow path extending in the up-down direction Z in the substrate 310.

The first connection flow path 336 is an L-shaped flow path that extends along the mounting surface 310a to couple the first flow path 331 and the discharge flow path 335. Specifically, a central portion of the first connection flow path 336 is coupled to the first flow path 331, one end of the first connection flow path 336 is coupled to the first discharge path 335a of the discharge flow path 335, and the other end of the first connection flow path 336 is coupled to the second discharge path 335b of the discharge flow path 335.

The second connection flow path 337 is an L-shaped flow path that extends along the mounting surface 310a to couple the second flow path 332 and the discharge flow path 335. Specifically, a central portion of the second connection flow path 337 is coupled to the second flow path 332, one end of the second connection flow path 337 is coupled to the second discharge path 335b of the discharge flow path 335, and the other end of the second connection flow path 337 is coupled to the fourth discharge path 335d of the discharge flow path 335.

The third connection flow path 338 is an L-shaped flow path that extends along the mounting surface 310a to couple the third flow path 333 and the discharge flow path 335. Specifically, a central portion of the third connection flow path 338 is coupled to the third flow path 333, one end of the third connection flow path 338 is coupled to the first discharge path 335a of the discharge flow path 335, and the other end of the third connection flow path 338 is coupled to the third discharge path 335c of the discharge flow path 335.

The fourth connection flow path 339 is an L-shaped flow path that extends along the mounting surface 310a to couple the fourth flow path 334 and the discharge flow path 335. Specifically, a central portion of the fourth connection flow path 339 is coupled to the fourth flow path 334, one end of the fourth connection flow path 339 is coupled to the third discharge path 335c of the discharge flow path 335, and the other end of the fourth connection flow path 339 is coupled to the fourth discharge path 335d of the discharge flow path 335.

The first connection flow path 336 and the third connection flow path 338 join in the first discharge path 335a, the first connection flow path 336 and the second connection flow path 337 join in the second discharge path 335b, the third connection flow path 338 and the fourth connection flow path 339 join in the third discharge path 335c, and the second connection flow path 337 and the fourth connection flow path 339 join in the fourth discharge path 335d.

The first connection flow path 336, the second connection flow path 337, the third connection flow path 338, and the fourth connection flow path 339 have a structure shaped like a quadrangular frame as a whole.

In the present modified example, the first connection flow path 336, the second connection flow path 337, the third connection flow path 338, and the fourth connection flow path 339 are formed in an upper layer (the second layer of the substrate 310) than the first flow path 331, the second flow path 332, the third flow path 333, and the fourth flow path 334 in the substrate 310. The first connection flow path 336, the second connection flow path 337, the third connection flow path 338, and the fourth connection flow path 339 may be formed in the same layer (the third layer 313 of the substrate 310) as the first flow path 331, the second flow path 332, the third flow path 333, and the fourth flow path 334.

In the laser irradiation apparatus 2C of the present modified example, since the flow rates of the coolant E supplied respectively to the first flow path 331 to the fourth flow path 334 branched in the four directions from the supply flow path 330 are the same, the temperature difference of the coolant E flowing through the respective flow paths 331 to 334 can be reduced.

Therefore, according to the laser irradiation apparatus 2C of the present modified example, it is possible to reduce the temperature variation among the laser elements 221a to 221d by reducing the difference in the cooling performance among the laser elements 221a to 221d with the respective flow paths 331 to 334.

In the present modified example, the first laser element 221a, the second laser element 221b, the third laser element 221c, and the fourth laser element 221d are any four adjacent laser elements out of the plurality of laser elements 221. Therefore, according to the laser irradiation apparatus 2C of the present modified example, it is possible to reduce the temperature variation among four adjacent laser elements out of the plurality of laser elements 221.

Therefore, the laser irradiation apparatus 2C of the present modified example can further stabilize the irradiation amount of the laser light L by suppressing the temperature variation among the four adjacent laser elements out of the plurality of laser elements 221.

In the configuration of the present modified example, it is possible to adopt a configuration in which the first connection flow path 336, the second connection flow path 337, the third connection flow path 338, and the fourth connection flow path 339 each have a circular arc shape, and are coupled to each other to thereby form a circular frame shape as a whole.

### Fourth Modified Example

FIG. 7 is a diagram showing a configuration of a main part of a laser irradiation apparatus according to a fourth modified example. FIG. 7 is a plan view illustrating a configuration of a main part of a laser irradiation apparatus 2D viewed from the −Z side toward the +Z side. FIG. 7 is a diagram illustrating a peripheral configuration of a first laser element 221a, a second laser element 221b, and a third laser element 221c as any three laser elements adjacent to each other out of the plurality of laser elements 221 in the laser irradiation apparatus 2D.

As illustrated in FIG. 7, a cooling substrate 21D in the present modified example includes a substrate 410, a supply flow path 430, a first flow path 431, a second flow path 432, a third flow path 433, a discharge flow path 435, a first connection flow path 436, a second connection flow path 437, and a third connection flow path 438.

The first flow path 431 extends along a mounting surface 410a of the substrate 410, and cools the first laser element 221a via a third layer 413 of the substrate 410.

The second flow path 432 extends along the mounting surface 410a of the substrate 410, and cools the second laser element 221b via the third layer 413 of the substrate 410.

The third flow path 433 extends along the mounting surface 410a of the substrate 410, and cools the third laser element 221c via the third layer 413 of the substrate 410.

In the plan view of the mounting surface 410a, the first flow path 431, the second flow path 432, and the third flow path 433 are branched from the supply flow path 430 in three directions different from each other. In the case of the present modified example, the first flow path 431, the second flow path 432, and the third flow path 433 respectively extend in directions different by 120 degrees in the circumferential direction of the supply flow path 430.

In the plan view of the mounting surface 410a, the first laser element 221a, the second laser element 221b, and the third laser element 221c are arranged in a triangular lattice shape. The supply flow path 430 is located at the center of the triangular lattice.

The discharge flow path 435 in the present modified example includes a first discharge path 435a, a second discharge path 435b, and a third discharge path 435c. Each of the discharge paths 435a to 435c is a flow path extending in the up-down direction Z in the substrate 410.

The first connection flow path 436 is a flow path that extends along the mounting surface 410a to couple the first flow path 431 and the discharge flow path 435. The first connection flow path 436 has a shape obtained by coupling a pair of L-shapes in a line-symmetric relationship to each other. Specifically, a central portion of the first connection flow path 436 is coupled to the first flow path 431, one end of the first connection flow path 436 is coupled to the first discharge path 435a of the discharge flow path 435, and the other end of the first connection flow path 436 is coupled to the third discharge path 435c of the discharge flow path 435.

The second connection flow path 437 is an L-shaped flow path that extends along the mounting surface 410a to couple the second flow path 432 and the discharge flow path 435. Specifically, a central portion of the second connection flow path 437 is coupled to the second flow path 432, one end of the second connection flow path 437 is coupled to the first discharge path 435a of the discharge flow path 435, and the other end of the second connection flow path 437 is coupled to the second discharge path 435b of the discharge flow path 435.

The third connection flow path 438 is an L-shaped flow path that extends along the mounting surface 410a to couple the third flow path 433 and the discharge flow path 435. Specifically, a central portion of the third connection flow path 438 is coupled to the third flow path 433, one end of the third connection flow path 438 is coupled to the second discharge path 435b of the discharge flow path 435, and the other end of the third connection flow path 438 is coupled to the third discharge path 435c of the discharge flow path 435.

The first connection flow path 436 and the second connection flow path 437 join in the first discharge path 435a, the second connection flow path 437 and the third connection flow path 438 join in the second discharge path 435b, and the first connection flow path 436 and the third connection flow path 438 join in the third discharge path 435c.

The first connection flow path 436, the second connection flow path 437, and the third connection flow path 438 have a quadrangular frame shape as a whole.

In the present modified example, the first connection flow path 436, the second connection flow path 437, and the third connection flow path 438 are formed in an upper layer (the second layer of the substrate 410) than the first flow path 431, the second flow path 432, and the third flow path 433 in the substrate 410. The first connection flow path 436, the second connection flow path 437, and the third connection flow path 438 may be formed in the same layer (the third layer 413 of the substrate 410) as the first flow path 431, the second flow path 432, and the third flow path 433.

In the laser irradiation apparatus 2D of the present modified example, since the flow rates of the coolant E supplied respectively to the first flow path 431 to the third flow path 433 branched in the three directions from the supply flow path 430 are the same, the temperature difference of the coolant E flowing through the respective flow paths 431 to 433 can be reduced.

Therefore, according to the laser irradiation apparatus 2D of the present modified example, it is possible to reduce the temperature variation among the laser elements 221a to 221c by reducing the difference in the cooling performance among the laser elements 221a to 221c with the respective flow paths 431 to 433.

In the present modified example, the first laser element 221a, the second laser element 221b, and the third laser element 221c are any three adjacent laser elements out of the plurality of laser elements 221. Therefore, according to the laser irradiation apparatus 2D of the present modified example, it is possible to reduce the temperature variation among three adjacent laser elements out of the plurality of laser elements 221.

Therefore, the laser irradiation apparatus 2D of the present modified example can further stabilize the irradiation amount of the laser light L by suppressing the temperature variation among the three adjacent laser elements out of the plurality of laser elements 221.

In the configuration of the present modified example, it is possible to adopt a configuration in which the first connection flow path 436, the second connection flow path 437, and the third connection flow path 438 each have a circular arc shape, and are coupled to each other to thereby form a circular frame shape as a whole.

The present disclosure will be summarized below as appendices.

### Appendix 1

A laser irradiation apparatus including:
a laser array configured with a plurality of laser elements including a first laser element and a second laser element; and
a cooling substrate configured to cool the laser array, wherein
the cooling substrate includes:
a substrate including a mounting surface on which the laser array is mounted;
a supply flow path extending in a direction crossing the mounting surface and configured to supply a coolant to an inside of the substrate;
a first flow path extending along the mounting surface and configured to cool the first laser element via the substrate; and
a second flow path extending along the mounting surface and configured to cool the second laser element via the substrate,
in a plan view of the mounting surface, each of the first flow path and the second flow path is branched from the supply flow path between the first laser element and the second laser element, and
the coolant flows to the first flow path and the second flow path via the supply flow path.

According to the laser irradiation apparatus having this configuration, since the flow rates of the coolant branched from the supply flow path and supplied to the first flow path and the second flow path are the same, the temperature difference between the coolant flowing through the first flow path and the coolant flowing through the second flow path can be reduced. Accordingly, by reducing the difference between the cooling performance of the first laser element with the first flow path and the cooling performance of the second laser element with the second flow path, the temperature variation between the first laser element and the second laser element can be reduced.

In this configuration, for example, when the first laser element and the second laser element are any two adjacent laser elements out of the plurality of laser elements, the temperature variation between the two adjacent laser elements out of the plurality of laser elements can be reduced.

Therefore, according to this configuration, the irradiation amount of the laser light can be stabilized by suppressing the temperature variation between the first laser element and the second laser element adjacent to each other out of the plurality of laser elements.

### Appendix 2

The laser irradiation apparatus according to Appendix 1, wherein
the cooling substrate further includes
a discharge flow path extending in a direction crossing the mounting surface and configured to discharge, from the substrate, the coolant that cooled the first laser element and the second laser element.

According to this configuration, the coolant after cooling the laser element can be discharged to the outside of the cooling substrate.

### Appendix 3

The laser irradiation apparatus according to Appendix 2, wherein
in the plan view of the mounting surface, the discharge flow path is disposed at a position different from positions of the supply flow path, the first flow path, and the second flow path.

According to this configuration, since the discharge flow path does not affect the layout of the supply flow path, the first flow path, and the second flow path, it is possible to increase the degree of freedom in designing the supply flow path, the first flow path, and the second flow path.

### Appendix 4

The laser irradiation apparatus according to one of Appendices 2 and 3, wherein
the cooling substrate further includes:
a first connection flow path extending along the mounting surface and configured to couple the first flow path and the discharge flow path; and
a second connection flow path extending along the mounting surface and configured to couple the second flow path and the discharge flow path.

According to this configuration, the coolant heated by cooling the laser element can be discharged from the first flow path and the second flow path to the discharge flow path.

### Appendix 5

The laser irradiation apparatus according to any one of Appendices 1 to 4, wherein
the plurality of laser elements further includes a third laser element, and
in the plan view of the mounting surface, the third laser element is disposed at a position where the third laser element overlaps the supply flow path.

According to this configuration, the temperature variation among three adjacent laser elements out of the plurality of laser elements can be reduced.

### Appendix 6

The laser irradiation apparatus according to any one of Appendices 1 to 4, wherein
the plurality of laser elements further includes a third laser element, and
in the plan view of the mounting surface, the third laser element is disposed downstream of the first laser element in the first flow path or downstream of the second laser element in the second flow path.

According to this configuration, the temperature variation among three adjacent laser elements out of the plurality of laser elements can be reduced.

### Appendix 7

The laser irradiation apparatus according to any one of Appendices 1 to 4, wherein
the plurality of laser elements further includes a third laser element,
the cooling substrate further includes
a third flow path extending along the mounting surface and configured to cool the third laser element via the substrate, and
in the plan view of the mounting surface, the first flow path, the second flow path, and the third flow path are branched from the supply flow path in three directions different from each other, respectively.

According to this configuration, the temperature variation among three adjacent laser elements out of the plurality of laser elements can be reduced.

### Appendix 8

The laser irradiation apparatus according to any one of Appendices 1 to 4, wherein
the plurality of laser elements further includes a third laser element and a fourth laser element,
the cooling substrate further includes:
a third flow path extending along the mounting surface and configured to cool the third laser element via the substrate; and
a fourth flow path extending along the mounting surface and configured to cool the fourth laser element via the substrate, and
in the plan view of the mounting surface, the first flow path, the second flow path, the third flow path, and the fourth flow path are branched from the supply flow path in four directions different from each other, respectively.

According to this configuration, the temperature variation among four adjacent laser elements out of the plurality of laser elements can be reduced.

### Appendix 9

The laser irradiation apparatus according to any one of Appendices 1 to 8, wherein
each of the plurality of laser elements is a photonic crystal surface emitting laser element.

According to this configuration, the radiation angle of the laser light from each laser element can be narrowed.

### Appendix 10

A laser processing apparatus including:
the laser irradiation apparatus according to any one of Appendices 1 to 9; and
a stage on which a workpiece to be irradiated with the laser light by the laser irradiation apparatus is placed.

According to the laser processing apparatus of this configuration, by stabilizing the irradiation amount of the laser light to the workpiece, the workpiece can be accurately processed by the processing with the laser light.

What is claimed is:

1. A laser irradiation apparatus comprising:
a laser array configured with a plurality of laser elements including a first laser element and a second laser element; and
a cooling substrate configured to cool the laser array, wherein
the cooling substrate includes:
a substrate including a mounting surface on which the laser array is mounted;
a supply flow path extending in a direction crossing the mounting surface and configured to supply a coolant to an inside of the substrate;
a first flow path extending along the mounting surface and configured to cool the first laser element via the substrate; and
a second flow path extending along the mounting surface and configured to cool the second laser element via the substrate,
in a plan view of the mounting surface, each of the first flow path and the second flow path is branched from the supply flow path between the first laser element and the second laser element, and
the coolant flows to the first flow path and the second flow path via the supply flow path.

2. The laser irradiation apparatus according to claim 1, wherein
the cooling substrate further includes
a discharge flow path extending in a direction crossing the mounting surface and configured to discharge, from the substrate, the coolant that cooled the first laser element and the second laser element.

3. The laser irradiation apparatus according to claim 2, wherein
in the plan view of the mounting surface, the discharge flow path is disposed at a position different from positions of the supply flow path, the first flow path, and the second flow path.

4. The laser irradiation apparatus according to claim 2, wherein
the cooling substrate further includes:
a first connection flow path extending along the mounting surface and configured to couple the first flow path and the discharge flow path; and
a second connection flow path extending along the mounting surface and configured to couple the second flow path and the discharge flow path.

5. The laser irradiation apparatus according to claim 1, wherein
the plurality of laser elements further includes a third laser element, and
in the plan view of the mounting surface, the third laser element is disposed at a position where the third laser element overlaps the supply flow path.

6. The laser irradiation apparatus according to claim 1, wherein
the plurality of laser elements further includes a third laser element, and
in the plan view of the mounting surface, the third laser element is disposed downstream of the first laser element in the first flow path or downstream of the second laser element in the second flow path.

7. The laser irradiation apparatus according to claim 1, wherein
the plurality of laser elements further includes a third laser element,
the cooling substrate further includes
a third flow path extending along the mounting surface and configured to cool the third laser element via the substrate, and
in the plan view of the mounting surface, the first flow path, the second flow path, and the third flow path are branched from the supply flow path in three directions different from each other, respectively.

8. The laser irradiation apparatus according to claim 1, wherein
the plurality of laser elements further includes a third laser element and a fourth laser element,
the cooling substrate further includes:
a third flow path extending along the mounting surface and configured to cool the third laser element via the substrate; and
a fourth flow path extending along the mounting surface and configured to cool the fourth laser element via the substrate, and
in the plan view of the mounting surface, the first flow path, the second flow path, the third flow path, and the fourth flow path are branched from the supply flow path in four directions different from each other, respectively.

9. The laser irradiation apparatus according to claim 1, wherein
each of the plurality of laser elements is a photonic crystal surface emitting laser element.

10. A laser processing apparatus comprising:
the laser irradiation apparatus according to claim 1; and
a stage on which a workpiece to be irradiated with a laser light by the laser irradiation apparatus is placed.
